(19) United States
(12) Patent Application Publication
(10) Pub. No.: US 2009/0243048 A1
(43) Pub. Date: Oct. 1, 2009

(54) METALLIC NANOCRYSTAL ENCAPSULATION

(76) Inventors: Joel Dufourcq, Grenoble (FR); Laurent Vandroux, Le Cheylas (FR); Pierre Mur, Crolles (FR); Sylvie Bodnar, Trets (FR)

Correspondence Address: SCHWEGMAN, LUNDBERG & WOESSNER, P.A., P.O. BOX 2938, MINNEAPOLIS, MN, 55402, US

(21) Appl. No.: 12/055,262

(22) Filed: Mar. 25, 2008

(51) Int. Cl. H01L 23/58; H01L 21/469

(52) U.S. Cl. 257/632; 438/787; 257/E21.487

(57) ABSTRACT

A method of forming a device includes forming protective shells about metallic nanocrystals supported by a substrate. The metallic nanocrystals having protective shells are encapsulated with a layer formed with process parameters that are not compatible with the integrity of unprotected metallic nanocrystals.

### CROSS REFERENCE TO RELATED APPLICATION

This application is related to U.S. application Ser. No. ______, entitled “METALLIC NANOCRYSTAL PATTERING” (Attorney Docket No. 2800.005US1), filed ______, which application is incorporated herein by reference.

### BACKGROUND

Non-volatile nanocrystal transistor memory cells use a transistor floating gate as a charge storage region, transferring charge through a tunneling barrier to nanocrystals. The electrostatic properties of a nanocrystal layer are modified, influencing a subsurface channel between source and drain in a MOS transistor to represent various logical values.

### BRIEF DESCRIPTION OF THE DRAWINGS

FIG. 1 is a perspective block diagram of a device having a metal layer to be elaborated into metallic nanocrystals according to an example embodiment.

FIG. 2 is a perspective block diagram of a device illustrating formation or elaboration of metallic nanocrystals according to an example embodiment.

FIG. 3 is a side cross-section representation of an exposed metallic nanocrystal according to an example embodiment.

FIG. 4 is a side cross-section representation of a Silicon precursor exposed metallic nanocrystal according to an example embodiment.

FIG. 5 is a side cross-section representation of a metallic nanocrystal having a protective oxide shell according to an example embodiment.

FIG. 6 is a block cross-section representation of a memory device having patterned metallic nanocrystals according to an example embodiment.

### DETAILED DESCRIPTION

In the following description, reference is made to the accompanying drawings that form a part hereof, and in which is shown by way of illustration specific embodiments, which may be practiced. These embodiments are described in sufficient detail to enable those skilled in the art to practice embodiments of the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

Metallic nanocrystals are used in various embodiments to replace silicon nanocrystals in nanocrystal floating gate memories. Various methods and resulting devices forming protective shells are used to create patterned nanocrystal device for use in floating gate memories and other devices.

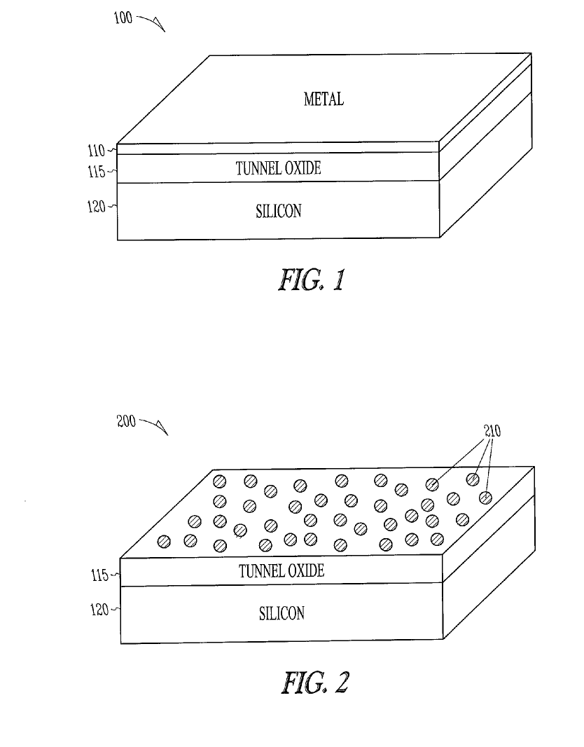

FIG. 1 is a perspective block diagram of a device 100 having a metal layer 110 to be elaborated into metallic nanocrystals according to an example embodiment. Metal layer 110 is supported by a tunnel oxide layer 115 supported by a substrate 120 in one embodiment.

FIG. 2 is a perspective block diagram of a device 200 illustrating formation or elaboration of metallic nanocrystals 210 supported by the substrate 120. Reference number 210 points to only a few of the metallic nanocrystals to simplify the drawing. In one embodiment, the metallic nanocrystals 210 are formed on the oxide layer 115 supported by the substrate 120.

Many different methods may be used to form the metallic nanocrystals 210, such as the use of physical vapor deposition of a thin metal layer 110, followed by a rapid thermal annealing in the 50-1200° C. temperature range. In some embodiments, rapid thermal annealing may be performed in the 200-1000° C. range in the case of Pt and Ni on oxide. In one embodiment, annealing the metal layer 110 results in formation of metallic dots, and forms the metallic nanocrystals 210, which are dispersed about the surface of oxide layer 115 such that they are physically separated from each other. FIG. 3 is a side cross-section representation of an exposed metallic nanocrystal 210 according to an example embodiment, wherein the numbering is consistent with FIGS. 1 and 2.

In one embodiment, the metallic nanocrystals may be formed with Pt. As an example, in the case of Pt nanocrystals with a density above 10¹²/cm², the distance between 2 nanocrystals (center to center) is above 4 nm. In one embodiment, the metallic nanocrystals 210 are fairly uniformly distributed about the surface of the oxide layer 115 with a density in the 10¹⁰−10¹⁴/cm² range and diameter ranging between 2 and 20 nm in various embodiments. The metallic nanocrystal 210 diameter is a function of the annealing time and thickness of the initial metal layer 110. For example, for Pt dots, the density could be 10¹²/cm² and the diameter in the 2-10 nm range. These parameters may be varied significantly in further embodiments.

Depending on the initial thickness of the metal layer 110 (continuous or not), the silanization process can lead to silanized metallic nanocrystals for low thickness of the initial metal layer 110 or a stabilized continuous layer for higher. initial thickness. For example, in the case of Pt, an initial Pt layer with a thickness in the range 1-5 nm leads to separated nanocrystals after annealing around 400° C. and an initial metal layer 110 with a thickness around 100 nm leads to a continuous stabilized layer after annealing in the same conditions.

In one embodiment, the metallic nanocrystals 210 include a metal nobler than silicon according to Ellingham diagrams, which are plots of the free energy of formation of a metal oxide per mole of oxygen (O₂) against temperature. Some example metals include but are not limited to Ni, Pt, Ag, and W. Further metals may include Ag and Au.

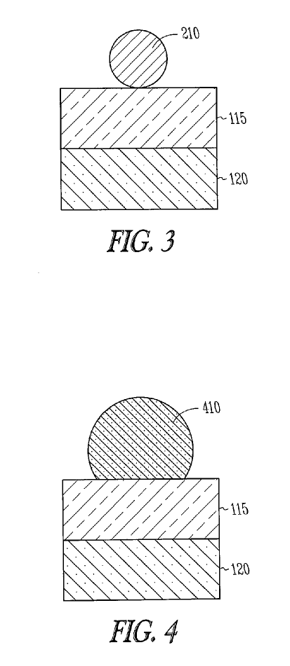

The metallic nanocrystals 210 are then exposed to a Silicon precursor gas, such as SiH₄, Si₂H₆, etc., at a low temperature, such as less than approximately 450° C. This creates a layer of silicon 410 covering the exposed metallic nanocrystals 210, one of which is shown in FIG. 4. This may also be referred to as silanization of the metallic nanoparticles. In one embodiment, the silicon layer 410 is thick enough to protect the metallic nanoparticles from further selected processing steps.

One approach of determining a proper thickness of the silicon layer 410 after silanization involves exposing the metallic nanocrystals 210 to an oxidant, annealing (for example 20% O₂ in nitrogen) and observing with MEB that there is no coalescence of the metallic nanocrystals 210. In one embodiment, dewetting may happen at the same time as the silanization.

In one embodiment, the silanized metallic nanocrystals 210 are exposed to an oxidizing environment, resulting in oxidation of the silicon layer 410 resulting in a silicon dioxide (SiO₂,) protective shell 510 as shown in cross section in FIG. 5. The protective shell 510 is thick enough to protect the metallic nanocrystals 210. The forming of the protective shell 510 may also be referred to as passivation of the metallic nanocrystals, e.g., 210.

In one embodiment, the protective shell 510 is formed by exposing the metallic nanocrystals 210 to a silicon precursor gas at a temperature less than approximately 450° C. For Pt metallic nanocrystals 210, an exposition to a SiH₄ flow at a temperature around 200° C. leads to the formation of a Si protective shell 510 around the metallic nanocrystals 210.

In one embodiment, the protective shell 510 may include a metal oxide having a metal similar or different to the metal used to form the metallic nanocrystals 210. The exposition of silanized metallic nanocrystals 210 formed of Ni (obtained using an exposition to a Silicon precursor at 200° C. for example) to an oxidant atmosphere at temperature above 200° C. could give a protective shell 510 formed by both Nickel oxide and Silicon oxide.

In some embodiments, the metals used for the nanocrystals are nobler than silicon or other material used to form the protective shell 510. This facilitates the oxidation of silanized nanocrystals, leading to formation of the protective shell 510 of oxide. In further embodiments, protection of the metallic nanocrystals 210 may be provided by other dielectric materials, such as nitrides or silicon with nitride for example.

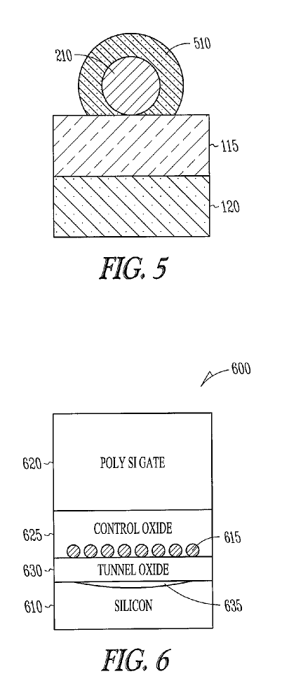

In one embodiment, a device 600 illustrated in FIG. 6 comprises silicon substrate 610, a patterned plurality of metallic nanocrystals 615 supported by the substrate 610, wherein the metallic nanoparticles 615 have protective oxide shells. Device 600 may be formed using CMOS processing technology. The patterned plurality of metallic nanocrystals 615 comprises a charge storage area for a memory device in one embodiment. A gate 620 is separated from the patterned plurality of metallic nanocrystals 615 by an electrically insulating layer 625, referred to as a control oxide having an electrical equivalent oxide (EOT) thickness in the 1-20 nm range in one embodiment. For example, in the case of high temperature oxidation (HTO), the thickness could be in the range 8-12 nm. The thickness of control oxide 625 may be varied significantly in further embodiments consistent with desired operation of the device. Layer 625 may be formed of a dielectric material such as SiO₂, HfA1O, HfO₂, ONO, SiON or an oxide in various embodiments.

The formation of the control oxide may be performed at a high temperature, in the 150-950° C. range (greater than 700° C. for HTO oxide deposition), and may also include oxidant precursors. The formation of the control oxide 625 may require thermal conditions which are not compatible with stability of high density and small size unprotected metallic nanocrystals 615. Without the process of embodiments of the invention, such temperatures may adversely affect non-encapsulated metallic nanocrystals, and may cause coalescence of the metallic nanocrystals 110, degrading their ability to hold a charge. When using the process of embodiments of the invention, such a temperature results in an oxide that helps maintain overall device 600 integrity and performance characteristics. The protective shells 510 serve to ensure that the metallic nanocrystals 615 maintain their integrity during formation of the control oxide, and function as desired to hold a charge.

A tunnel oxide 630 separates the patterned plurality of metallic nanocrystals 615 from substrate 610, which includes a transistor channel 635 formed in the substrate 610 opposite the tunnel oxide 630, patterned metallic nanocrystals 615 and gate 620 such that a charge on the metallic nanocrystals 615 affects the conductive properties of the transistor channel 635. Tunnel oxide 630 may have an equivalent oxide thickness in the 1-10 nm range in one embodiment and may be varied significantly in further embodiments. Especially for SiO₂, the thickness may be in the 30-60 nm range. Typical materials for tunnel oxide 630 include but are not limited to SiO₂, SiON, HfA1O, and HfO₂. Other materials may also be used.

In one method of forming a device that includes metallic nanocrystals, the silanization or passivation (passivation includes silanization followed by reoxidation) of the metallic nanocrystals 615 before deposition of the control dielectric helps block metallic nanocrystal diffusion on the tunnel dielectric surface. The passivation in one embodiment begins with a selective deposition of silicon on the metallic nanocrystals. The deposition method may be a chemical vapor deposition with a silicon precursor such as silane (SiH₄), disilane (Si₂H₆), trisilane (Si₃H₈) or other gaseous precursor of silicon. The temperature of the deposition may be selected to avoid diffusion of metal on the tunnel dielectric surface and to allow catalytic reaction between the silicon precursor and the metal. It is a compromise between temperature and pressure. One such temperature range may be above 25° C. and less than approximately 450° C. for SiH₄ used on Pt dots.

In one embodiment, selective silicon deposition is performed on the metallic nanocrystals without inter-diffusion between metal and silicon. In a further embodiment, a selective silanization of the metallic nanocrystals results in the formation of a metal-Si compound by reaction between the silicon of the gaseous precursor and the metal of the nanocrystals.

Next, a selective oxidation of the silicon part present on the metallic nanocrystals encapsulates the metallic nanocrystals in a protective shell of oxide. The selective oxidation occurs when the metal of the nanocrystals is nobler than the material to be oxidized to form the shell. In the case of silicon, a silicon oxide shell is formed and may be thermodynamically stable around the metallic nanocrystals.

Several different oxidation processes may be used, such as natural air oxidation, an annealing under an oxidant atmosphere such as O₂, NO₂, NO, etc., or a chemical oxidation using an oxidant liquid solution that is aqueous or organic. At this point, the nanocrystals are passivated and ready to be encapsulated with a control dielectric. The control dielectric may be deposited at high temperature to form a high quality control oxide. In various embodiments, the temperature used for dielectric process may range from 150 to 900° C. For HTO, the temperature may be around or above 700° C.

In a further embodiment, a metal for the metallic nanocrystals is selected that oxidizes in ambient air (especially Ni). This leads to ensuring that no exposure to ambient air is allowed between the metallic nanocrystal formation and the beginning of silanization or passivation. In a further embodiment, the metallic nanocrystals may be formed with several different metal alloys, such as PtNi. In such a case, the metallic nanocrystal is formed with a core of one metal such as Pt, and is then surrounded by a shell of an oxide of the second metal, such as NiO.

The Abstract is provided to comply with 37 C.F.R. §1.72(b) to allow the reader to quickly ascertain the nature and gist of the technical disclosure. The Abstract is submitted with the understanding that it will not be used to interpret or limit the scope or meaning of the claims.

1. A method comprising:
forming protective shells about metallic nanocrystals supported by a substrate; and
encapsulating the metallic nanocrystals having protective shells with an oxide layer formed at process parameters that would adversely affect non-encapsulated metallic nanocrystals.

2. The method of claim 1 wherein encapsulating the metallic nanocrystals having protective shells comprises forming an oxide layer at temperatures exceeding approximately 150° C.

3. The method of claim 1 wherein the protective shells comprise silicon dioxide (SiO₂).

4. The method of claim 3 wherein the metallic nanocrystals comprise a metal nobler than silicon.

5. The method of claim 1 wherein the metallic nanocrystals are selected from the group consisting of Ni, Pt, Ag, and W.

6. The method of claim 1 wherein forming protective shells comprises silanizing the metallic nanocrystals and exposing the silanized metallic nanocrystals to an oxidant atmosphere.

7. The method of claim 1 wherein forming protective shells comprises exposing the metallic nanocrystals to an adapted silicon precursor gas at a temperature less than approximately 450° C.

9. The method of claim 1 wherein the protective shell comprises a metal oxide having a metal different than a core metal of the metallic nanocrystal.

10. A method comprising:
forming protective shells about metallic nanocrystals supported by a substrate;
exposing the metallic nanocrystals having the protective shells to an oxidant atmosphere; and
forming an oxide layer at temperatures exceeding approximately 150° C. that encapsulates the metallic nanocrystals having protective shells.

11. The method of claim 10 wherein the protective shells comprise silicon dioxide (SiO₂).

12. The method of claim 11 wherein the metallic nanocrystals comprise a metal nobler than silicon.

13. The method of claim 10 wherein the metallic nanocrystals are selected from the group consisting of Ni, Pt, Ag, and W.

14. The method of claim 10 wherein forming protective shells comprises silanizing the exposed metallic nanocrystals and exposing the silanized metallic nanocrystals to an oxidant atmosphere.

15. The method of claim 10 wherein forming protective shells comprises exposing the exposed metallic nanocrystals to an adapted silicon precursor gas at a temperature less than approximately 450° C.

16. The method of claim 10 wherein the protective shell comprises a metal oxide having a metal different than a core metal of the metallic nanocrystal.

17. A device comprising:
a substrate;
a plurality of metallic nanocrystals supported by the substrate, the metallic nanoparticles having protective oxide shells;
an oxide layer supported by the substrate and encapsulating the plurality of metallic nanocrystals.

18. The device of claim 17 wherein the protective oxide shells comprise SiO₂.

19. The device of claim 17 wherein the plurality of nanocrystals comprise a charge storage area for a memory device.

20. The device of claim 17 and further comprising:
a gate separated from the plurality of metallic nanocrystals by the oxide layer;
a tunnel oxide supported by the substrate and formed under the metallic nanocrystals; and
a transistor channel opposite the tunnel oxide, metallic nanocrystals and gate such that a charge on the metallic nanocrystals affects the conductive properties of the transistor channel.
